(19) United States
(12) Patent Application Publication
(10) Pub. No.: US 2026/0149414 A1
(43) Pub. Date: May 28, 2026

(54) AMPLIFICATION DEVICE AND CURRENT MIRROR CIRCUIT THEREOF

(71) Applicant: RichWave Technology Corp., Taipei City (TW)

(72) Inventors: Tien-Yun Peng, Taipei City (TW); Chih-Sheng Chen, Taipei City (TW)

(73) Assignee: RichWave Technology Corp., Taipei City (TW)

(21) Appl. No.: 18/970,853

(22) Filed: Dec. 5, 2024

(30) Foreign Application Priority Data
Nov. 22, 2024 (TW) 113145043

(51) Int. Cl. H03F 1/22; H03F 1/30

(52) U.S. Cl. CPC H03F 1/223; H03F 1/301; H03F 2200/474

(57) ABSTRACT

In an amplification device, a signal input terminal receives an input signal. A signal output terminal outputs an amplified signal. An amplification circuit is coupled between the signal input terminal and the signal output terminal, and includes a first transistor and a second transistor coupled in a cascode manner. A third transistor receives a first reference current. A fourth transistor receives a second reference current. A fifth transistor receives a third reference current and is coupled to the fourth transistor. An operational amplifier is coupled to the third transistor and the amplification circuit. A distance from the fourth transistor to a transistor in the amplification circuit is less than a distance from the fifth transistor to the same transistor. The fourth transistor is used to detect temperature changes for compensation.

### TECHNICAL FIELD

The disclosure is related to an amplification device and a current mirror circuit thereof, particularly to an amplification device and a current mirror circuit thereof configured to detect temperature changes for compensation.

### BACKGROUND

In radio frequency (RF) applications, an amplification device may include an amplification circuit used to convert low-power RF signals into high-power RF signals. The amplification circuit may for example include a low noise amplifier (LNA) and a power amplifier (PA). The amplification device may further include circuits that provide bias voltage and/or bias current for the amplification circuit, such as a current mirror circuit.

Current mirror circuits are prevalent in analog circuits. The precision of these circuits is crucial, as the stability and accuracy of their output current may directly impact performance. Current mirrors may be implemented using components like metal-oxide-semiconductor field-effect transistors (MOSFETs). In amplification circuits, such as low noise amplifiers, current mirrors may be switched between ON and OFF states. However, thermal effects due to temperature fluctuations may cause unexpected variations in the current, and the operating state of the amplification circuit may thus be shift, resulting in a reduced accuracy. Additionally, the history effect of transistors may make it challenging to maintain a desired current level. Therefore, a more suitable solution is needed to address at least one of these issues.

### SUMMARY

An embodiment provides an amplification device comprising a signal input terminal, a signal output terminal, an amplification circuit, a third transistor, a fourth transistor, a fifth transistor, and an operational amplifier. The signal input terminal is configured to receive an input signal. The signal output terminal is configured to output an amplified signal. The amplification circuit is coupled between the signal input terminal and the signal output terminal, and the amplification circuit comprises a first transistor and a second transistor coupled in a cascode manner, wherein a first node is coupled between the first transistor and the second transistor, the first node has a first voltage, and the amplification circuit is coupled to a first reference voltage terminal. The third transistor comprises a first terminal, a second terminal, and a control terminal, wherein the first terminal of the third transistor is coupled to a second reference voltage terminal, the second terminal of the third transistor is coupled to a third node, the third node is configured to receive a first reference current, and the third node has a third voltage. The fourth transistor comprises a first terminal, a second terminal, and a control terminal, wherein the first terminal of the fourth transistor is coupled to a third reference voltage terminal, the second terminal of the fourth transistor is coupled to a fourth node, the fourth node is configured to receive a second reference current, and the fourth node has a fourth voltage. The fifth transistor comprises a first terminal, a second terminal, and a control terminal, wherein the first terminal of the fifth transistor is coupled to a fourth reference voltage terminal, the second terminal of the fifth transistor is coupled to the control terminal of the fifth transistor and the control terminal of the fourth transistor, and the second terminal of the fifth transistor is configured to receive a third reference current. The operational amplifier comprises a first input terminal, a second input terminal, and an output terminal, wherein the first input terminal of the operational amplifier is coupled to the fourth node, the second input terminal of the operational amplifier is coupled to the third node N3, and the output terminal of the operational amplifier is coupled to the amplification circuit and the control terminal of the third transistor. In a chip, a distance from the fourth transistor to a transistor in the amplification circuit is less than a distance from the fifth transistor to the transistor in the amplification circuit.

Another embodiment provides an amplification device comprising a signal input terminal, a signal output terminal, an amplification circuit, a third transistor, a fourth transistor, a fifth transistor, and an operational amplifier. The signal input terminal is configured to receive an input signal. The signal output terminal is configured to output an amplified signal. The amplification circuit is coupled between the signal input terminal and the signal output terminal, and the amplification circuit comprises a first transistor and a second transistor coupled in a cascode manner, wherein a first node is coupled between the first transistor and the second transistor, the first node has a first voltage, the amplification circuit is coupled to a first reference voltage terminal. The third transistor comprises a first terminal, a second terminal, and a control terminal, wherein the first terminal of the third transistor is coupled to a second reference voltage terminal, the second terminal of third transistor is coupled to a third node, the third node is configured to receive a first reference current, and the third node has a third voltage. The fourth transistor comprises a first terminal, a second terminal, and a control terminal, wherein the first terminal of the fourth transistor is coupled to a third reference voltage terminal, the second terminal of the fourth transistor is coupled to a fourth node, the fourth node is configured to receive a second reference current, and the fourth node has a fourth voltage. The fifth transistor comprises a first terminal, a second terminal, and a control terminal, wherein the first terminal of the fifth transistor is coupled to a fourth reference voltage terminal, the second terminal of the fifth transistor is coupled to the control terminal of the fifth transistor and the control terminal of the fourth transistor, and the second terminal of the fifth transistor is configured to receive a third reference current. The operational amplifier comprises a first input terminal, a second input terminal, and an output terminal, wherein the first input terminal of the operational amplifier is coupled to the fourth node, the second input terminal of the operational amplifier is coupled to the third node, and the output terminal of the operational amplifier is coupled to the amplification circuit and the control terminal of the third transistor. During an operation period, a temperature difference between the fourth transistor and the amplification circuit is less than a temperature difference between the fifth transistor and the amplification circuit.

Another embodiment provides a current mirror circuit for adjusting a load current of an amplification circuit. The current mirror circuit comprises a third transistor, a fourth transistor, a fifth transistor, and an operational amplifier. The third transistor comprises a first terminal, a second terminal, and a control terminal, wherein the first terminal of the third transistor is coupled to a second reference voltage terminal, the second terminal of the third transistor is coupled to a third node, the third node is configured to receive a first reference current, and the third node has a third voltage. The fourth transistor comprises a first terminal, a second terminal, and a control terminal, wherein the first terminal of the fourth transistor is coupled to a third reference voltage terminal, the second terminal of the fourth transistor is coupled to a fourth node, the fourth node is configured to receive a second reference current, and the fourth node has a fourth voltage. The fifth transistor comprises a first terminal, a second terminal, and a control terminal, wherein the first terminal of the fifth transistor is coupled to a fourth reference voltage terminal, the second terminal of the fifth transistor is coupled to the control terminal of the fifth transistor and the control terminal of the fourth transistor, and the second terminal of the fifth transistor is configured to receive a third reference current. The operational amplifier comprises a first input terminal, a second input terminal, and an output terminal, wherein the first input terminal of the operational amplifier is coupled to the fourth node, the second input terminal of the operational amplifier is coupled to the third node, and the output terminal of the operational amplifier is coupled to the amplification circuit and the control terminal of the third transistor. In a chip, a distance from the fourth transistor to a transistor in the amplification circuit is less than a distance from the fifth transistor to the transistor in the amplification circuit.

### BRIEF DESCRIPTION OF THE DRAWINGS

FIG. 1 shows an amplification device according to an embodiment.

FIG. 2 shows a layout diagram of some transistors in an amplification device according to one embodiment.

FIG. 3 shows an amplification device according to another embodiment.

FIG. 4 shows a layout diagram of some transistors in an amplification device according to another embodiment.

FIG. 5 shows an amplification device according to another embodiment.

FIG. 6 shows an amplification device according to another embodiment.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

In the following specification and claims, terms “comprising,” “including,” and “having” are open-ended terms, and therefore should be interpreted as “including but not limited to.” Thus, when the description of the present invention uses the terms “comprising,” “including,” and/or “having,” it specifies the presence of the corresponding features, regions, steps, operations, and/or components, but does not exclude the presence of other features, regions, steps, operations, and/or components.

It should be noted that the following embodiments may be replaced, reorganized, and combined with features from different embodiments without departing from the spirit of the present invention to complete other embodiments. The features of the embodiments may be mixed and matched as long as they do not contradict or conflict with the spirit of the invention.

When referring to a field effect transistor herein, the first terminal may correspond to one of the source and the drain, the second terminal may correspond to the other, and the control terminal may correspond to the gate. When referring to a bipolar transistor, the first terminal may correspond to one of the collector and the emitter, the second terminal may correspond to the other, and the control terminal may correspond to the base.

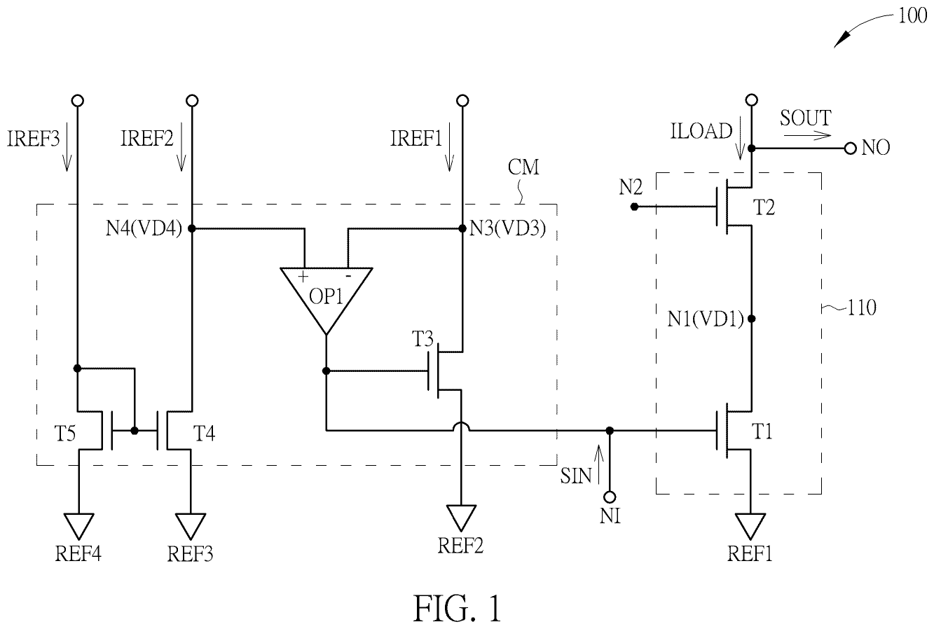

FIG. 1 shows an amplification device 100 according to one embodiment. As shown in FIG. 1, in an embodiment, the amplification device 100 may be used to convert low-power radio frequency (RF) signals into high-power RF signals. The amplification device 100 may include a current mirror circuit CM and an amplification circuit 110. In FIG. 1, the current mirror circuit CM and the amplification circuit 110 are distinguished by dashed boxes, but this is only for the convenience of description and not intended to limit the invention. In other embodiments, the current mirror circuit CM and the amplification circuit 110 may each include elements different from those shown in FIG. 1, or the current mirror circuit CM and the amplification circuit 110 may include shared common elements. For example, the current mirror circuit CM may include transistors drawn in the amplification circuit 110.

In an embodiment, the amplification device 100 may include a signal input terminal NI and a signal output terminal NO. The signal input terminal NI may be used to receive an input signal SIN. The signal output terminal NO may be used to output an amplified signal SOUT. The amplified signal SOUT may be a signal generated by amplifying the input signal SIN. The amplification circuit 110 may be coupled between the signal input terminal NI and the signal output terminal NO, and may include a first transistor T1 and a second transistor T2 coupled in a cascode manner. The amplification circuit 110 is not limited to the structure shown in FIG. 1. In other embodiments, the amplification circuit 110 may include more transistors coupled in a cascode manner. The first transistor T1 and the second transistor T2 may be directly cascode-connected, or indirectly cascode-connected where a third transistor, an active component, and/or a passive component may present between the first transistor T1 and the second transistor T2.

As shown in the illustrated embodiment, the first transistor T1 may include a first terminal, a second terminal, and a control terminal. The first terminal may be coupled to a first reference voltage terminal REF1, the second terminal may be coupled to a first node N1, and the control terminal may be coupled to the signal input terminal NI. The second transistor T2 may include a first terminal, a second terminal, and a control terminal. The first terminal may be coupled to the first node N1, the second terminal may be coupled to the signal output terminal NO, and the control terminal may be coupled to a second node N2. In other words, the first node N1 may be coupled between the first transistor T1 and the second transistor T2. Furthermore, the first node N1 may have a first voltage VD1, which will be described further below.

For example, in a case where the first transistor T1 and the second transistor T2 are directly coupled in the cascode manner, the second terminal of the first transistor T1 may be directly coupled to the first node N1, and the first terminal of the second transistor T2 may be directly coupled to the first node N1. In another case where the first transistor T1 and the second transistor T2 are indirectly coupled in a cascade manner, for instance, additional transistors may be used between the second terminal of the first transistor T1 and the first node N1, or between the first node N1 and the first terminal of the second transistor T2.

In an embodiment, the current mirror circuit CM may include a third transistor T3, a fourth transistor T4, a fifth transistor T5, and an operational amplifier OP1. Specifically, the third transistor T3 may include a first terminal, a second terminal, and a control terminal. The first terminal may be coupled to a second reference voltage terminal REF2, and the second terminal may be coupled to a third node N3. The fourth transistor T4 may include a first terminal, a second terminal, and a control terminal. The first terminal may be coupled to a third reference voltage terminal REF3, and the second terminal may be coupled to a fourth node N4. The fifth transistor T5 may include a first terminal, a second terminal, and a control terminal. The first terminal may be coupled to a fourth reference voltage terminal REF4, and the second terminal may be coupled to the control terminal of the fifth transistor T5. Furthermore, the second terminal and the control terminal of the fifth transistor T5 may be further coupled to the control terminal of the fourth transistor T4.

In the abovementioned embodiments, the second terminal of the third transistor T3 may receive a first reference current IREF1 through the third node N3, and the third node N3 may have a third voltage VD3. In other words, the third node N3 may be used to receive the first reference current IREF1, and the path of the first reference current IREF1 may include the path where the third transistor T3 is located. The second terminal of the fourth transistor T4 may receive a second reference current IREF2 through the fourth node N4, and the fourth node N4 may have a fourth voltage VD4. In other words, the fourth node N4 may be used to receive the second reference current IREF2, and the path of the second reference current IREF2 may include the path where the fourth transistor T4 is located. Furthermore, the second terminal of the fifth transistor T5 may be used to receive a third reference current IREF3, and the path of the third reference current IREF3 may include the path where the fifth transistor T5 is located. Details will be described below.

In an embodiment, the operational amplifier OP1 may include a first input terminal, a second input terminal, and an output terminal. The first input terminal of the operational amplifier OP1 may be coupled to the fourth node N4, and further coupled to the second terminal of the fourth transistor T4. The second input terminal of the operational amplifier OP1 may be coupled to the third node N3, and further coupled to the second terminal of the third transistor T3. The output terminal of the operational amplifier OP1 may be coupled to the amplification circuit 110, for example, coupled to the control terminal of the first transistor T1 of the amplification circuit 110. Furthermore, the output terminal of the operational amplifier OP1 may also be coupled to the control terminal of the third transistor T3, which will be further described below. For example, the first input terminal of the operational amplifier OP1 may be one of the positive input terminal and the negative input terminal, and the second input terminal of the operational amplifier OP1 may be the other one of the positive input terminal and the negative input terminal. In the illustrated embodiment, the first input terminal of the operational amplifier OP1 is the positive input terminal, and the second input terminal of the operational amplifier OP1 is the negative input terminal.

In an embodiment, a load current ILOAD may flow through the amplification circuit 110, and the current mirror circuit CM may be used to adjust the load current ILOAD of the amplification circuit 110. The path of the load current ILOAD may include the path where the first transistor T1 and the second transistor T2 are located. The current flowing through the first transistor T1 and the second transistor T2 may cause the temperature of the first transistor T1 and/or the second transistor T2 to rise. The heating of the first transistor T1 and the second transistor T2 may depend on the operating power. For example, a higher operating power may result in a greater heating and a greater temperature changes.

During operation, the fourth transistor T4 may be used to detect temperature changes of the amplification circuit 110. For example, the temperature of the amplification circuit 110 may depend on an averaged temperature of the first transistor T1 and the second transistor T2. In the chip, the distance from the fourth transistor T4 to a predetermined transistor in the amplification circuit 110 (e.g., the first transistor T1 or the second transistor T2) may be less than the distance from the fifth transistor T5 to the predetermined transistor. Alternatively, during operation, the temperature difference between the fourth transistor T4 and the amplification circuit 110 may be less than the temperature difference between the fifth transistor T5 and the amplification circuit 110.

In an embodiment, during operation, one of the first transistor T1 and the second transistor T2 in the amplification circuit 110 may have a higher temperature than the other. In this case, when configuring the circuit layout, the position of the fourth transistor T4 in the chip may be arranged to be close to the transistor with the higher temperature, so that the temperature of the fourth transistor T4 may track the temperature of the higher temperature transistor. Specifically, if simulations indicate that the temperature of the first transistor T1 is higher than that of the second transistor T2 during operation, the position of the fourth transistor T4 in the chip may be arranged to be close to the first transistor T1, so the distance between the fourth transistor T4 and the first transistor T1 is smaller, for example, smaller than the distance between the fifth transistor T5 and the first transistor T1.

In another embodiment, during operation, the temperatures of the first transistor T1 and the second transistor T2 may be substantially the same. In this case, the position of the fourth transistor T4 in the chip may be arranged to be close to both transistors, allowing the temperature of the fourth transistor T4 to track the temperatures of both transistors. Specifically, if simulations indicate that the temperature of the first transistor T1 is substantially equal to the temperature of the second transistor T2 during operation, the position of the fourth transistor T4 in the chip may be arranged to be close to both the first transistor T1 and the second transistor T2. This means that the sum of the distance between the fourth transistor T4 and the first transistor T1 and the distance between the fourth transistor T4 and the second transistor T2 is less than the sum of the distance between the fifth transistor T5 and the first transistor T1 and the distance between the fifth transistor T5 and the second transistor T2. In a specific embodiment, the distance between the fourth transistor T4 and the first transistor T1 in the chip is less than the distance between the fifth transistor T5 and the first transistor T1, and the distance between the fourth transistor T4 and the second transistor T2 is less than the distance between the fifth transistor T5 and the second transistor T2, such that the fourth transistor T4 may detect temperature changes of the first transistor T1 and the second transistor T2.

It should be noted that although FIG. 1 depicts the first transistor T1 as a single transistor, a person skilled in the art may recognize that the first transistor T1 may include at least one transistor unit. For example, in the case where field-effect transistors (FETs) are used, each transistor unit may include at least one gate. Furthermore, each transistor unit may further include a source and a drain, and adjacent transistor units may share the source or the drain. Additionally, in the case where bipolar junction transistors (BJTs) are used, each transistor unit may include at least one base. Moreover, in the disclosure, when referring to the size of a transistor, it may be characterized by the number of transistor units the transistor comprises, such as the number of gates. Specifically, in the case where the gates are finger-shaped, the number of transistor units may be equal to the number of finger-shaped gates. Alternatively, the size of the transistor may also be characterized by at least one of the following: gate width, width-to-length ratio (W/L ratio), etc.

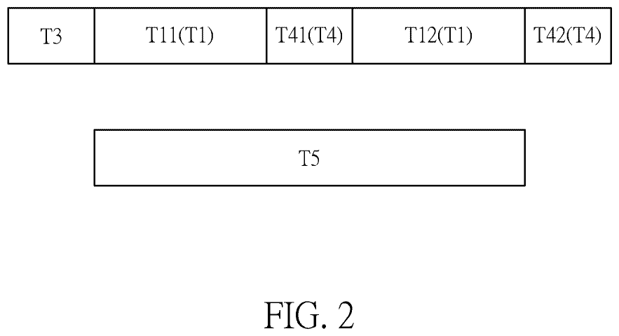

FIG. 2 shows a layout diagram of some transistors in the amplification device according to an embodiment. FIG. 2 may be a top view, illustrating the positions of transistors in the chip layout without providing precise dimensions. The layout diagram in FIG. 2 may be appropriately adjusted and still fall within the scope of the present disclosure.

As shown in FIG. 2, the first transistor T1 may include a first set of transistor units T11 and a second set of transistor units T12. The fourth transistor T4 may include a first set of transistor units T41 and a second set of transistor units T42. As previously mentioned, the temperature of the first transistor T1 during operation may be higher than that of the second transistor T2, for example. In this exemplary case, the position of the fourth transistor T4 in the chip may be arranged to be close to the first transistor T1 to detect temperature changes of the first transistor T1.

Specifically, in the chip, the first set of transistor units T41 of the fourth transistor T4 may be adjacent to the first set of transistor units T11 of the first transistor T1 and adjacent to the second set of transistor units T12 of the first transistor T1. For example, the first set of transistor units T41 may be placed between the first set of transistor units T11 and the second set of transistor units T12 of the first transistor T1. Furthermore, the second set of transistor units T42 of the fourth transistor T4 may be adjacent to the second set of transistor units T12 of the first transistor T1. FIG. 2 also illustrates the position of the fifth transistor T5 in the chip. As shown, the distance from the fourth transistor T4 (including the first set of transistor units T41 and the second set of transistor units T42) to the first transistor T1 (including the first set of transistor units T11 and the second set of transistor units T12) may be less than the distance from the fifth transistor T5 to the first transistor T1.

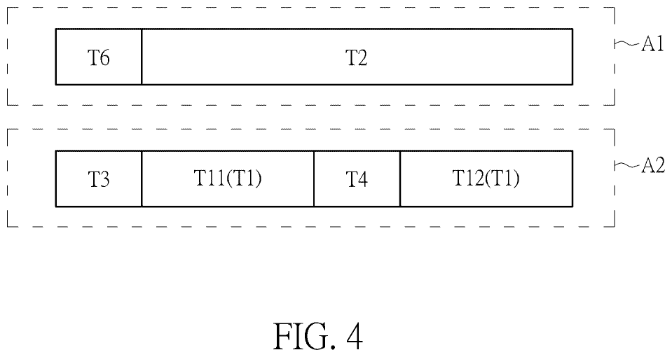

In an embodiment, for the fourth transistor T4, the first set of transistor units T41 may include m transistor units, and the second set of transistor units T42 of the fourth transistor T4 may include n transistor units, where m and n may be positive integers. The temperature of the fourth transistor T4 may depend on the averaged temperature of the first set of transistor units T41 and the second set of transistor units T42. In a further embodiment, m may be substantially equal to n. As described above, the number of transistor units may be counted, for example, by the number of finger-shaped gates. FIG. 2 also illustrates the position of the third transistor T3 in the chip, which will be further described below with reference to FIG. 4.

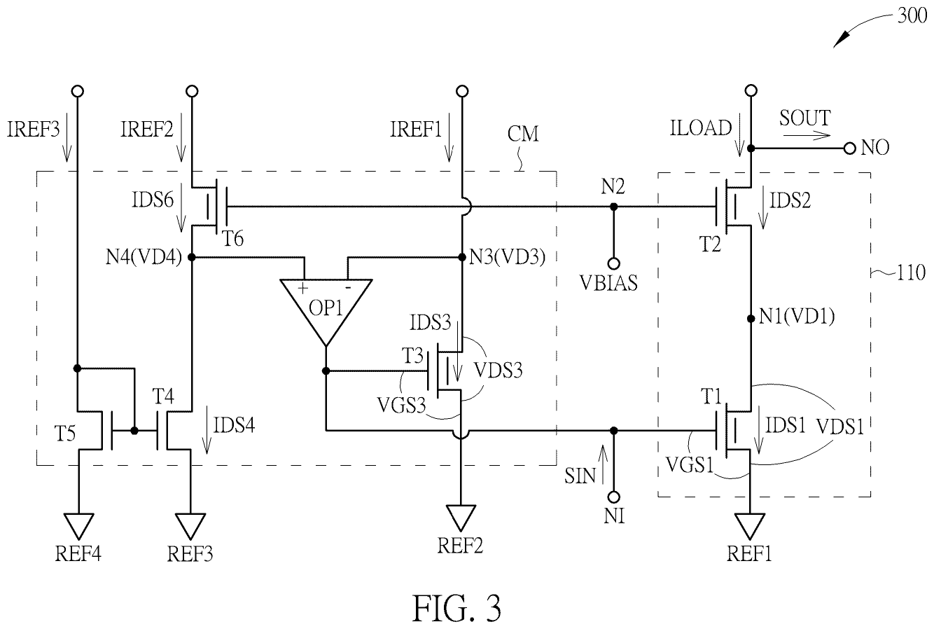

FIG. 3 shows an amplification device 300 according to another embodiment. The amplification device 300 may be similar to the amplification device 100, and the similarities will not be reiterated. The amplification device 300 may further include a sixth transistor T6. The sixth transistor T6 may include a first terminal, a second terminal, and a control terminal. The first terminal of the sixth transistor T6 may be coupled to the fourth node N4, thereby further coupling to the second terminal of the fourth transistor T4. The second terminal of the sixth transistor T6 may be used to receive the second reference current IREF2. Furthermore, the control terminal of the sixth transistor T6 may be coupled to the second node N2. As described above, the control terminal of the second transistor T2 may be coupled to the second node N2. Therefore, the control terminal of the sixth transistor T6 is coupled to the control terminal of the second transistor T2 via the second node N2. In this case, the path of the second reference current IREF2 may include the path where the sixth transistor T6 and the fourth transistor T4 are located. Furthermore, the second node N2 may be additionally coupled to a bias voltage terminal VBIAS, which may be used to provide a bias voltage signal with a predetermined or variable level.

In an embodiment, the first transistor T1 and the third transistor T3 may be fabricated using substantially the same process, so that they may present substantially the same process/voltage/temperature (PVT) performance. Specifically, the first transistor T1 and the third transistor T3 may have substantially the same process variation parameter, also known as process corner parameters. The process corner parameters may be used to evaluate different transistor performance variations due to the manufacturing process. For example, in the case of MOSFETs, the process corner parameters may include cases such as T-T, F-F, S-S, F-S, and S-F. The first letter represents the operating speed of the N-type transistor, and the second letter represents the operating speed of the P-type transistor. T stands for typical operating speed, F stands for fast operating speed, and S stands for slow operating speed. Generally, those skilled in the art may understand the meaning of these parameters and thus they are not further detailed here.

Furthermore, the second transistor T2 and the sixth transistor T6 may be fabricated using substantially the same process, so that they may have substantially the same process variation parameters. Specifically, the second transistor T2 and the sixth transistor T6 may present substantially the same process/voltage/temperature (PVT) performance.

Furthermore, in the chip layout, the third transistor T3 may be positioned close to the first transistor T1, so that the third transistor T3 and the first transistor T1 may form a desirable current mirror structure. Specifically, the distance from the third transistor T3 to the first transistor T1 may be less than the distance from the third transistor T3 to the second transistor T2. Similarly, in the chip layout, the sixth transistor T6 may be positioned close to the second transistor T2, so that the sixth transistor T6 and the second transistor T2 may form a desirable current mirror structure. Specifically, the distance from the sixth transistor T6 to the second transistor T2 may be less than the distance from the sixth transistor T6 to the first transistor T1.

FIG. 4 shows some the transistor layout in the amplification device according to another embodiment. FIG. 4 may be a top view, illustrating the position of the transistors in the chip layout without providing precise dimensions. The layout diagram in FIG. 4 may be appropriately adjusted and still fall within the scope of the present disclosure.

As shown in FIG. 4, the sixth transistor T6 and the second transistor T2 may be arranged in the same area, shown as area A1. As mentioned above, the second transistor T2 and the sixth transistor T6 may form a current mirror structure. Placing the sixth transistor T6 and the second transistor T2 in the same area (e.g., area A1) may be helpful to achieve a desirable current mirror performance. The third transistor T3 and the first transistor T1 may be arranged in the same area, shown as area A2, to achieve desirable current mirror performance. Furthermore, the fourth transistor T4 may also be arranged in area A2 to track the temperature of the first transistor T1, as mentioned above with reference to FIG. 2. Specifically, the third transistor T3 may be adjacent to the first set of transistor units T11 of the first transistor T1, and the fourth transistor T4 may be placed between the first set of transistor units T11 and the second set of transistor units T12 of the first transistor T1.

In some embodiments, as described above, the third transistor T3 and the first transistor T1 may form a current mirror structure. The first transistor T1 and the third transistor T3 may each include a body terminal, and their body terminals may be in the same connection state. For example, the body terminal of the first transistor T1 and the body terminal of the third transistor T3 may be floating, where the body terminals do not have a predetermined voltage. Similarly, as described above, the sixth transistor T6 and the second transistor T2 may form a current mirror structure. The second transistor T2 and the sixth transistor T6 may each include a body terminal, and their body terminals may be in the same connection state. For example, the body terminal of the second transistor T2 and the body terminal of the sixth transistor T6 may be contacted or tied, where the body terminal has a predetermined voltage level. However, the invention is not limited thereto. For example, in other embodiments, the body terminal of the first transistor T1 and the body terminal of the third transistor T3 may be contacted. Or, the body terminal of the second transistor T2 and the body terminal of the sixth transistor T6 may be floating.

Generally, in a current mirror structure, the current flowing through a transistor may be directly related to its width-to-length ratio (W/L ratio). If two transistors have the same W/L ratio, the current flowing through each transistor may be the same. If two transistors have different W/L ratios, the current flowing through each transistor may be scaled accordingly. For example, if one transistor has a W/L ratio that is twice that of the other transistor, the current flowing through the former may be twice that of the latter.

In the embodiment of FIG. 3, in the path of the load current ILOAD, the load current ILOAD may be substantially equal to the current IDS2 flowing through the second transistor T2, and equal to the current IDS1 flowing through the first transistor T1. In the path of the first reference current IREF1, the first reference current IREF1 may be substantially equal to the current IDS3 flowing through the third transistor T3.

Furthermore, referring to FIG. 3, the first transistor T1 may be defined by a first size S1, and the third transistor T3 may be defined by a third size S3. In the current mirror structure formed by the first transistor T1 and the third transistor T3, the current IDS1 flowing between the first terminal and the second terminal of the first transistor T1, and the current IDS3 flowing between the first terminal and the second terminal of the third transistor T3, may be related to the aforementioned sizes. Specifically, the ratio of the first size S1 to the third size S3 may be substantially equal to the ratio of the current IDS1 to the current IDS3, which may be generally expressed as S1/S3=IDS1/IDS3. For example, if the first size S1 is X times the third size S3, then the current IDS1 may be X times the current IDS3. Here, X may be, for example, 1, 20, 50, or other suitable values.

As described above, the current IDS2 flowing through the second transistor T2 may be related to the current IDS6 flowing through the sixth transistor T6. Therefore, the load current ILOAD may be related to the first reference current IREF1.

Similarly, the second transistor T2 may be defined by a second size S2, and the sixth transistor T6 may be defined by a sixth size S6. In the current mirror structure formed by the second transistor T2 and the sixth transistor T6, the current IDS2 flowing between the first terminal and the second terminal of the second transistor T2, and the current IDS6 flowing between the first terminal and the second terminal of the sixth transistor T6 may be related to the aforementioned sizes. Specifically, the ratio of the second size S2 to the sixth size S6 may be substantially equal to the ratio of the current IDS2 to the current IDS6, which may be generally expressed as S2/S6=IDS2/IDS6. For example, if the second size S2 is Y times the sixth size S6, then the current IDS2 may be Y times the current IDS6. Here, Y may be, for example, 1, 20, 50, or other suitable values.

Additionally, in the path of the second reference current IREF2, the second reference current IREF2 may be substantially equal to the current IDS6 flowing through the sixth transistor T6, and equal to the current IDS4 flowing through the fourth transistor T4. In the path of the third reference current IREF3, the third reference current IREF3 may be substantially equal to the current IDS5 flowing through the fifth transistor T5 (not shown).

In an embodiment, the operational amplifier OP1 may be used to maintain the third voltage VD3 of the third node N3 substantially equal to the fourth voltage VD4 of the fourth node N4. For example, when the fourth voltage VD4 decreases, the third voltage VD3 may decrease accordingly. In other words, by configuring the operational amplifier OP1, the third voltage VD3 may track the fourth voltage VD4 to be substantially equal to the fourth voltage VD4.

Furthermore, the output terminal of the operational amplifier OP1 may be coupled to the control terminal of the first transistor T1 and the control terminal of the third transistor T3, so that the voltage at the control terminal of the first transistor T1 may be substantially equal to the voltage at the control terminal of the third transistor T3. In some embodiments, the first reference voltage terminal REF1 and the second reference voltage terminal REF2 may provide reference voltages at the same level. For example, the first reference voltage terminal REF1 and the second reference voltage terminal REF2 may be ground terminals. In this case, the voltage difference VGS3 between the control terminal and the first terminal of the third transistor T3 may be substantially equal to the voltage difference VGS1 between the control terminal and the first terminal of the first transistor T1. As described above, in some embodiments, the first transistor T1 and the third transistor T3 may be fabricated using substantially the same process. In this case, the voltage difference VDS3 between the second terminal and the first terminal of the third transistor T3 may be substantially equal to the voltage difference VDS1 between the second terminal and the first terminal of the first transistor T1. Since the third voltage VD3 at the third node N3 may depend on the value of the voltage difference VDS3, and the first voltage VD1 at the first node N1 may depend on the value of the voltage difference VDS1, the third voltage VD3 may be substantially equal to the first voltage VD1. Furthermore, the third voltage VD3, the fourth voltage VD4, and the first voltage VD1 may be substantially equal to each other.

For example, the first terminal, the second terminal, and the control terminal of the first transistor T1 may correspond to the source, the drain, and the gate, respectively. In this case, the voltage difference VGS1 may be the gate-source voltage difference of the first transistor T1, and the voltage difference VDS1 may be the drain-source voltage difference of the first transistor T1. However, the invention is not limited thereto. In other embodiments, the first terminal, the second terminal, and the control terminal of the first transistor T1 may correspond to the emitter, the collector, and the base, respectively.

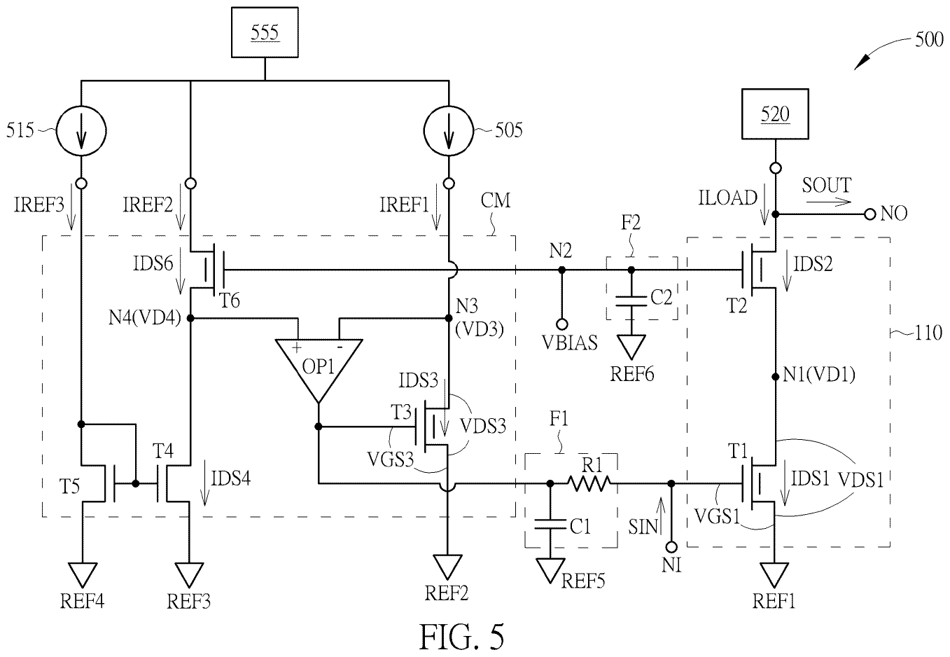

FIG. 5 shows an amplification device 500 according to another embodiment. The amplification device 500 may be similar to the amplification device 100 and/or the amplification device 300, and the similarities will not be reiterated. The amplification device 500 may further include a load circuit 520, which may be coupled to the second terminal of the second transistor T2. For example, the load circuit 520 may include a low dropout regulator (LDO) or other circuits. The amplification device 500 may further include current source circuits 505 and 515 respectively coupled to the third transistor T3 and the fifth transistor T5, so as to respectively provide the first reference current IREF1 and the third reference current IREF3.The current source circuits 505 and 515 may be further coupled to a voltage source circuit 555 to receive a supply voltage. Generally, it is desired that the gain of the amplification circuit 110 does not change with temperature variations, in order to maintain desirable linearity. However, in practice, current may cause the temperature of the amplification circuit 110 to rise, leading to an undesirable decrease in its gain.

In some embodiments, as described above, at the beginning of the operation, the third voltage VD3 at the third node N3 may be substantially equal to the first voltage VD1 at the first node N1. During operation, the temperature of the first transistor T1 and/or the second transistor T2 may rise. For example, if the first transistor T1 has a higher temperature than the second transistor T2, the fourth transistor T4 may be located close to the first transistor T1 to detect temperature changes of the first transistor T1, thereby providing compensation. For example, the distance from the fourth transistor T4 to the first transistor T1 is less than the distance from the fifth transistor T5 to the first transistor T1.

Specifically, when the temperature of the first transistor T1 rises, the temperature of the fourth transistor T4 also rises, causing the threshold voltage of the fourth transistor T4 to decrease. The threshold voltage (Vth) may be, for example, a gate-source threshold voltage (Vgs(th)). Therefore, the current IDS4 flowing through the fourth transistor T4 may increase, and the current IDS6 flowing through the sixth transistor T6 may also increase. In this case, the fourth voltage VD4 at the fourth node N4 may decrease.

By configuring the operational amplifier OP1, the third voltage VD3 at the third node N3 may follow the fourth voltage VD4 to decrease. Therefore, the third voltage VD3 at the third node N3 may be lower than the first voltage VD1 at the first node N1. In the current mirror structure formed by the first transistor T1 and the third transistor T3, the third voltage VD3 lower than the first voltage VD1 may cause the current IDS1 flowing through the first transistor T1 to increase. In this configuration, since the fifth transistor T5 is relatively farther from the first transistor T1, its threshold voltage may remain substantially unchanged, or may change by a small extent.

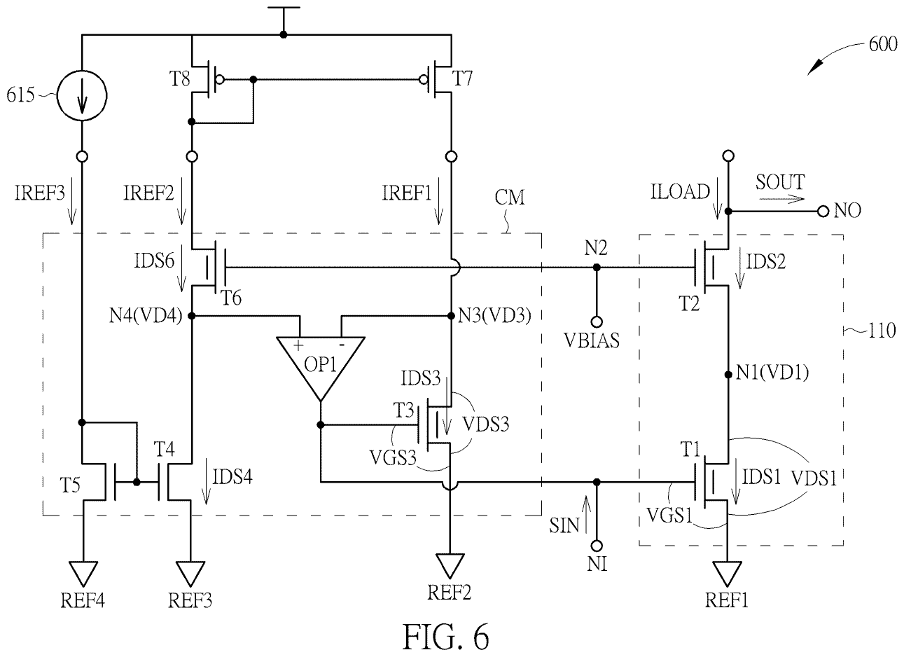

FIG. 6 shows an amplification device 600 according to another embodiment. The amplification device 600 may be similar to the amplification device 100, the amplification device 300 and/or the amplification device 500, and the similarities will not be reiterated. The amplification device 600 may further include a current source circuit 615, a seventh transistor T7, and an eighth transistor T8. In this embodiment, the seventh transistor T7 may be, for example, a specific embodiment of the current source circuit 505 shown in FIG. 5. The seventh transistor T7 and the eighth transistor T8 may form a current mirror structure.

Specifically, when the temperature of the first transistor T1 increases, the temperature of the fourth transistor T4 also increases, so that the gate-source threshold voltage Vgs(th) of the fourth transistor T4 decreases. Therefore, the current IDS4 flowing through the fourth transistor T4 and the current IDS6 flowing through the sixth transistor T6 may both increase. That is, the second reference current IREF2 may increase. With the current mirror structure formed by the seventh transistor T7 and the eighth transistor T8, the first reference current IREF1 may also increase. In the path of the first reference current IREF1, an increase in the first reference current IREF1 may cause an increase in the current IDS3 flowing through the third transistor T3. Further with the current mirror structure formed by the first transistor T1 and the third transistor T3, the current IDS1 flowing through the first transistor T1 may increase.

For example, the increase in the current IDS1 may be based on the ratio of the first size S1 of the first transistor T1 to the third size S3 of the third transistor T3. As a result, the current IDS1 flowing through the first transistor T1 may increase, thereby compensating for the gain of the amplification circuit 110.

In other embodiments, during operation, the second transistor T2 may have a higher temperature than the first transistor T1. The fourth transistor T4 may be positioned close to the second transistor T2 to detect temperature changes of the second transistor T2, thereby providing compensation. For example, the distance from the fourth transistor T4 to the second transistor T2 may be less than the distance from the fifth transistor T5 to the second transistor T2.

In some embodiments, during operation, the temperatures of the first transistor T1 and the second transistor T2 may be substantially the same. The fourth transistor T4 may be positioned close to both the first transistor T1 and the second transistor T2 to detect temperature changes of both transistors. For example, the sum of the distance from the fourth transistor T4 to the first transistor T1 and the distance from the fourth transistor T4 to the second transistor T2 may be less than the sum of the distance from the fifth transistor T5 to the first transistor T1 and the distance from the fifth transistor T5 to the second transistor T2. Specifically, the distance from the fourth transistor T4 to the first transistor T1 may be less than the distance from the fifth transistor T5 to the first transistor T1, and the distance from the fourth transistor T4 to the second transistor T2 may be less than the distance from the fifth transistor T5 to the second transistor T2.

In some embodiments, during operation, other components of the amplification circuit 110, such as the load circuit 520, may have a higher temperature. The fourth transistor T4 may be positioned close to the load circuit 520 to detect temperature changes of the load circuit 520, thereby providing compensation.

As shown in FIG. 5, in some embodiments, the amplification device 500 may further include a first filter circuit F1 coupled to the signal input terminal NI. The first filter circuit F1, for example, may be coupled between the signal input terminal NI and the output terminal of the operational amplifier OP1, so as to avoid unexpected impact of the input signal SIN on the operational amplifier OP1. For example, it may prevent or mitigate the interference caused by the RF (radio-frequency) components in the input signal SIN on the operational amplifier OP1. Specifically, the first filter circuit F1 may include a first capacitor C1 and a first resistor R1. The first terminal of the first capacitor C1 is coupled to the fifth reference voltage terminal REF5. The first terminal of the first resistor R1 may be coupled to the second terminal of the first capacitor C1, and the second terminal of the first resistor R1 may be coupled to the signal input terminal NI.

In some embodiments, the amplification device 500 may further include a second filter circuit F2, which may be coupled to the second node N2. The second filter circuit F2, for example, may be coupled between the control terminal of the second transistor T2 and the control terminal of the sixth transistor T6, so as to avoid unexpected impact of the amplified signal SOUT on the sixth transistor T6. Specifically, the second filter circuit F2 may include a second capacitor C2, and the second capacitor C2 may have a first terminal coupled to the sixth reference voltage terminal REF6, and a second terminal coupled to the second node N2. In the above embodiments, the first filter circuit F1 and the second filter circuit F2 are examples, and other suitable filter circuit structures may also be within the scope of embodiments.

In at least one of the above embodiments, the first reference voltage terminal REF1, the second reference voltage terminal REF2, the third reference voltage terminal REF3, the fourth reference voltage terminal REF4, the fifth reference voltage terminal REF5, and the sixth reference voltage terminal REF6 may provide reference voltages at the same level or at different levels. For example, at least one of these reference voltage terminals may be a ground terminal.

In summary, in at least one embodiment of the present disclosure, by using the fourth transistor T4 in the current mirror circuit to detect the temperature of the amplification circuit (e.g., at least one of the first transistor T1 and the second transistor T2), or to detect the temperature of a circuit related to the amplification circuit (e.g., a load circuit), the gain of the amplification circuit 110 may be compensated. Therefore, the gain of the amplification circuit may be less affected by the temperature changes, so as to improve the performance of the circuit.

In this document, certain features, elements, structures, materials, configurations, etc., may be exemplarily described in one embodiment, but the invention is not limited to that embodiment. For example, elements described in one embodiment may be omitted from that embodiment, or may be applied to another embodiment. Certain terms are used in the specification and the appended claims to refer to specific elements. It should be understood by those skilled in the art that manufacturers of electronic devices may refer to the same elements by different names. This document is not intended to distinguish between elements that perform the same function but are named differently.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An amplification device comprising:
a signal input terminal configured to receive an input signal;
a signal output terminal configured to output an amplified signal;
an amplification circuit coupled between the signal input terminal and the signal output terminal, the amplification circuit comprising a first transistor and a second transistor coupled in a cascode manner, wherein a first node is coupled between the first transistor and the second transistor, the first node has a first voltage, and the amplification circuit is coupled to a first reference voltage terminal;
a third transistor comprising a first terminal, a second terminal, and a control terminal, wherein the first terminal of the third transistor is coupled to a second reference voltage terminal, the second terminal of the third transistor is coupled to a third node, the third node is configured to receive a first reference current, and the third node has a third voltage;
a fourth transistor comprising a first terminal, a second terminal, and a control terminal, wherein the first terminal of the fourth transistor is coupled to a third reference voltage terminal, the second terminal of the fourth transistor is coupled to a fourth node, the fourth node is configured to receive a second reference current, and the fourth node has a fourth voltage;
a fifth transistor comprising a first terminal, a second terminal, and a control terminal, wherein the first terminal of the fifth transistor is coupled to a fourth reference voltage terminal, the second terminal of the fifth transistor is coupled to the control terminal of the fifth transistor and the control terminal of the fourth transistor, and the second terminal of the fifth transistor is configured to receive a third reference current; and
an operational amplifier comprising a first input terminal, a second input terminal, and an output terminal, wherein the first input terminal of the operational amplifier is coupled to the fourth node, the second input terminal of the operational amplifier is coupled to the third node N3, and the output terminal of the operational amplifier is coupled to the amplification circuit and the control terminal of the third transistor;
wherein in a chip, a distance from the fourth transistor to a transistor in the amplification circuit is less than a distance from the fifth transistor to the transistor in the amplification circuit.

2. The amplification device of claim 1, wherein:
the first transistor comprises a first terminal, a second terminal, and a control terminal, wherein the first terminal of the first transistor is coupled to the first reference voltage terminal, the second terminal of the first transistor is coupled to the first node, and the control terminal of the first transistor is coupled to the signal input terminal and the output terminal of the operational amplifier; and
the second transistor comprises a first terminal, a second terminal, and a control terminal, wherein the first terminal of the second transistor is coupled to the first node, the second terminal of the second transistor is coupled to the signal output terminal, and the control terminal of the second transistor is coupled to a second node.

3. The amplification device of claim 2, wherein:
during an operation period, one of the first transistor and the second transistor has a higher temperature than the other, and in the chip, a distance from the fourth transistor to the one with the higher temperature is less than a distance from the fifth transistor to the one with the higher temperature.

4. The amplification device of claim 3, wherein:
the fourth transistor comprises a first set of transistor units and a second set of transistor units; and
in the chip, a distance from the first set of transistor units of the fourth transistor to the one with the higher temperature is less than a distance from the fifth transistor to the one with the higher temperature.

5. The amplification device of claim 4, wherein:
in the chip, a distance between the second set of transistor units of the fourth transistor to the one with the higher temperature is less than a distance from the fifth transistor to the one with the higher temperature.

6. The amplification device of claim 4, wherein:
the first set of transistor units comprises m transistor units, the second set of transistor units comprises n transistor units, m and n are positive integers, and m is substantially equal to n.

7. The amplification device of claim 2, wherein:
during an operation period, the first transistor and the second transistor substantially have a same temperature; and
in the chip, a distance from the fourth transistor to the first transistor is less than a distance from the fifth transistor to the first transistor, and a distance from the fourth transistor to the second transistor is less than a distance from the fifth transistor to the second transistor.

8. The amplification device of claim 2, wherein:
a voltage difference between the control terminal and the first terminal of the third transistor is substantially equal to a voltage difference between the control terminal and the first terminal of the first transistor; and
a voltage difference between the second terminal and the first terminal of the third transistor is substantially equal to a voltage difference between the second terminal and the first terminal of the first transistor.

9. The amplification device of claim 2, wherein:
the third voltage is substantially equal to the fourth voltage; and
the first voltage is substantially equal to the fourth voltage.

10. The amplification device of claim 2, wherein:
the first transistor and the third transistor have a same process variation parameter; and
in the chip, a distance from the third transistor to the first transistor is less than a distance from the third transistor to the second transistor.

11. The amplification device of claim 1, wherein:
a load current flows through the amplification circuit, and the load current is related to the first reference current.

12. The amplification device of claim 11, wherein:
the first transistor is defined by a first size, the third transistor is defined by a third size, and a ratio of the first size to the third size is substantially equal to a ratio of the load current to the first reference current.

13. The amplification device of claim 2, further comprising:
a sixth transistor comprising a first terminal, a second terminal, and a control terminal, wherein the first terminal of the sixth transistor is coupled to the fourth node, the second terminal of the sixth transistor is configured to receive the second reference current, and the control terminal of the sixth transistor is coupled to the second node.

14. The amplification device of claim 13, wherein:
the second transistor and the sixth transistor have a same process variation parameter; and
in the chip, a distance from the sixth transistor to the second transistor is less than a distance from the sixth transistor to the first transistor.

15. The amplification device of claim 13, wherein:
the first transistor further comprises a body terminal, the third transistor further comprises a body terminal, and a connection state of the body terminal of the first transistor is same as a connection state of the body terminal of the third transistor; and
the second transistor further comprises a body terminal, the sixth transistor further comprises a body terminal, and a connection state of the body terminal of the second transistor is same as a connection state of the body terminal of the sixth transistor.

16. The amplification device of claim 13, wherein the amplification circuit further comprises:
a first filter circuit coupled between the signal input terminal of the amplification device and the output terminal of the operational amplifier; and
a second filter circuit coupled between the control terminal of the second transistor and the control terminal of the sixth transistor.

17. An amplification device comprising:
a signal input terminal configured to receive an input signal;
a signal output terminal configured to output an amplified signal;
an amplification circuit coupled between the signal input terminal and the signal output terminal, the amplification circuit comprising a first transistor and a second transistor coupled in a cascode manner, wherein a first node is coupled between the first transistor and the second transistor, the first node has a first voltage, the amplification circuit is further coupled to a first reference voltage terminal;
a third transistor comprising a first terminal, a second terminal, and a control terminal, wherein the first terminal of the third transistor is coupled to a second reference voltage terminal, the second terminal of third transistor is coupled to a third node, the third node is configured to receive a first reference current, and the third node has a third voltage;
a fourth transistor comprising a first terminal, a second terminal, and a control terminal, wherein the first terminal of the fourth transistor is coupled to a third reference voltage terminal, the second terminal of the fourth transistor is coupled to a fourth node, the fourth node is configured to receive a second reference current, and the fourth node has a fourth voltage;
a fifth transistor comprising a first terminal, a second terminal, and a control terminal, wherein the first terminal of the fifth transistor is coupled to a fourth reference voltage terminal, the second terminal of the fifth transistor is coupled to the control terminal of the fifth transistor and the control terminal of the fourth transistor, and the second terminal of the fifth transistor is configured to receive a third reference current; and
an operational amplifier comprising a first input terminal, a second input terminal, and an output terminal, wherein the first input terminal of the operational amplifier is coupled to the fourth node, the second input terminal of the operational amplifier is coupled to the third node, and the output terminal of the operational amplifier is coupled to the amplification circuit and the control terminal of the third transistor;
wherein during an operation period, a temperature difference between the fourth transistor and the amplification circuit is less than a temperature difference between the fifth transistor and the amplification circuit.

18. The amplification device of claim 17, wherein:
during the operation period, a temperature of the amplification circuit is determined based on an averaged temperature of the first transistor and the second transistor.

19. The amplification device of claim 17, wherein:
the fourth transistor comprises a first set of transistor units and a second set of transistor units, and a temperature of the fourth transistor is determined based on an averaged temperature of the first set of transistor units and the second set of transistor units.

20. A current mirror circuit for adjusting a load current of an amplification circuit, the current
mirror circuit comprising:
a third transistor comprising a first terminal, a second terminal, and a control terminal, wherein the first terminal of the third transistor is coupled to a second reference voltage terminal, the second terminal of the third transistor is coupled to a third node, the third node is configured to receive a first reference current, and the third node has a third voltage;
a fourth transistor comprising a first terminal, a second terminal, and a control terminal, wherein the first terminal of the fourth transistor is coupled to a third reference voltage terminal, the second terminal of the fourth transistor is coupled to a fourth node, the fourth node is configured to receive a second reference current, and the fourth node has a fourth voltage;
a fifth transistor comprising a first terminal, a second terminal, and a control terminal, wherein the first terminal of the fifth transistor is coupled to a fourth reference voltage terminal, the second terminal of the fifth transistor is coupled to the control terminal of the fifth transistor and the control terminal of the fourth transistor, and the second terminal of the fifth transistor is configured to receive a third reference current; and
an operational amplifier comprising a first input terminal, a second input terminal, and an output terminal, wherein the first input terminal of the operational amplifier is coupled to the fourth node, the second input terminal of the operational amplifier is coupled to the third node, and the output terminal of the operational amplifier is coupled to the amplification circuit and the control terminal of the third transistor;
wherein in a chip, a distance from the fourth transistor to a transistor in the amplification circuit is less than a distance from the fifth transistor to the transistor in the amplification circuit.
